(19) United States
(12) Patent Application Publication
(10) Pub. No.: US 2025/0031407 A1
(43) Pub. Date: Jan. 23, 2025

(54) SIC SEMICONDUCTOR DEVICE IMPLEMENTED ON INSULATING OR SEMI-INSULATING SIC SUBSTRATE AND MANUFACTURING METHOD THEREOF

(71) Applicant: KOREA ELECTROTECHNOLOGY RESEARCH INSTITUTE, Changwon-si, Gyeongsangnam-do (KR)

(72) Inventors: Hyoung Woo KIM, Changwon-si, Gyeongsangnam-do (KR); Jeong Hyun MOON, Gimhae-si, Gyeongsangnam-do (KR); Wook BAHNG, Changwon-si, Gyeongsangnam-do (KR); Jae Hwa SEO, Seoul (KR)

(21) Appl. No.: 18/715,087

(22) PCT Filed: Mar. 7, 2022
(86) PCT No.: PCT/KR2022/003192

§ 371 Date: May 30, 2024

(30) Foreign Application Priority Data
Dec. 20, 2021 (KR) 10-2021-0182695

(51) Int. Cl. H01L 29/78; H01L 21/265; H01L 21/266; H01L 29/06; H01L 29/16; H01L 29/66

(52) U.S. Cl. CPC H01L 29/7824; H01L 21/26506; H01L 29/0623; H01L 29/66681; H01L 21/266; H01L 29/1608

(57) ABSTRACT

A SiC semiconductor device having high pressure resistance properties is disclosed. The present invention provides a SiC semiconductor device comprising: a SiC substrate having a first surface and a second surface; an insulating area formed on the second surface side inside the SiC substrate; and a plurality of semiconductor areas including a source area, a base area, and a drain area formed along the first surface on the insulating area, wherein the SiC semiconductor device has a P/N junction parallel to the first surface, the P/N junction extending from the base area toward the drain area on the insulating area and being formed by a first auxiliary region of a first conductive type which is the same conductive type as the source area and a second auxiliary region of a second conductive type which is opposed to the first conductive type.

### TECHNICAL FIELD

The disclosure relates to a SiC semiconductor device and a manufacturing method thereof and, more specifically, to a SiC semiconductor device having high withstand voltage characteristics and a manufacturing method thereof.

### BACKGROUND ART

A silicon carbide (SiC)-based semiconductor device which exhibits superior characteristics compared to existing silicon (Si) devices is attracting attention as a device which can satisfy high power and switching characteristics due to excellent properties thereof such as high breakdown voltage, thermal conductivity, and fast electron flow speed.

A high voltage silicon carbide lateral metal oxide semiconductor field effect transistor (LMOSFET) is manufactured by forming a silicon carbide epitaxial layer on a silicon carbide (SiC) substrate and then forming a required area by ion implantation. Such a typical LMOSFET manufacturing process has a disadvantage that an expensive epitaxial layer formation process must be carried out separately, and when a P-epilayer is formed on an N-substrate, the leakage current to the substrate is large.

Recently, a power MOSFET which improves the breakdown voltage and on-resistance of a power semiconductor device using a charge compensation effect has been proposed. In 1995, J. Tihanyi of Siemens proposed a vertical DMOSFET in which the P pillar and N pillar were arranged throughout a drift area. Here, the N-pillar serves as a path through which current flows when the gate voltage is above a threshold voltage and a positive voltage is applied to a drain, and in a reverse bias state where the gate voltage is 0 V and a positive voltage is applied to the drain, the P-pillar creates a mutual charge compensation effect with the N-pillar, and serves to help a depletion layer expand from a P-base to the drain.

Meanwhile, in a case of a lateral MOS device, attempts are being made to obtain a high breakdown voltage. FIG. 1 is a diagram showing a typical structure of a silicon-based lateral MOSFET using a pillar structure.

Referring to FIG. 1, a super-junction layer in which N-pillar and P-pillar semiconductor regions are alternately arranged is formed on a P-type substrate. This structure is configured to obtain a high breakdown voltage due to charge compensation between the P-pillar and the N-pillar and to lower the on-resistance by doping the pillars at a high concentration. However, in this structure, the breakdown voltage is rapidly reduced due to the depletion effect caused by the P substrate in addition to the depletion effect between the pillars. In order to solve this problem, attempts are being made to use an additional buffer layer or a sapphire substrate, but this structure has an issue that a new process must be introduced to solve the problem.

### DISCLOSURE OF INVENTION

### Technical Problem

An aspect of the disclosure is to provide an insulating or semi-insulating SiC substrate-based SiC semiconductor device having high withstand voltage characteristics.

Another aspect of the disclosure is to provide a SiC semiconductor device having high withstand voltage characteristics using a charge compensation effect.

Another aspect of the disclosure is to provide a SiC semiconductor device having easy control of charge balance required for charge compensation to provide high breakdown voltage.

Another aspect of the disclosure is to provide a method of manufacturing a SiC semiconductor device on an insulating or semi-insulating substrate.

Another aspect of the disclosure is to provide a method of manufacturing a SiC semiconductor device having high withstand voltage characteristics by ion implantation process.

### Solution to Problem

In order to solve the above technical problems, the disclosure provides a SiC semiconductor device including a plurality of semiconductor regions including an insulation region formed at a second surface side in a SiC substrate having a first surface and a second surface, a source region formed on the insulation region along the first surface, a base region, and a drain region, wherein the SiC semiconductor device includes a P/N junction surface extending from the base region toward the drain region on the insulation region, formed by a first auxiliary region of a first conductivity type which is the same conductivity type as the source region and a second auxiliary region of a second conductivity type opposite to the first conductivity type, and parallel to the first surface.

In the disclosure, the first auxiliary region may be disposed on the second auxiliary region. Alternatively, the first auxiliary region may be disposed beneath the second auxiliary region.

In the disclosure, it is preferable that the doping concentration of the first auxiliary region is lower than the doping concentration of the source region.

In the disclosure, the ratio of the doping concentration of the second auxiliary region to the first auxiliary region may be in the range of 0.7 to 1.3.

In the disclosure, the length of the first auxiliary region may be designed to be substantially the same as that of the second auxiliary region, or the length of the second auxiliary region may be designed to be greater than the length of the first auxiliary region.

In the disclosure, the insulation region has an electrical resistance of 10⁵Ω-cm or more.

In the disclosure, the base region may extend between the source region and the current path region to a lower end of the source region to form a junction with the source region.

In the disclosure, it is preferable that the thickness (or junction depth) of the first auxiliary region is equal to or greater than the thickness of the source region. In the disclosure, the dopant concentration of the source and drain regions may be 10¹⁸ to 10²¹/cm³, and the dopant concentration of the base region may be 1*10¹⁷ to 5*10¹⁷/cm³.

In the disclosure, the dopant concentration of the first auxiliary region may be 10¹⁵/cm³ to 10¹⁷/cm³. In addition, the dopant concentration of the second auxiliary region may be 10¹⁵/cm³ to 10¹⁷/cm³.

In the disclosure, the semiconductor device may be a MOSFET or CMOS device.

In order to solve the above technical problems, the disclosure may include: providing an insulating or semi-insulating SiC substrate; implanting a dopant into the SiC substrate to form a plurality of semiconductor regions; and forming electrodes to electrically connect the plurality of doped regions on the SiC substrate, wherein the operation of forming a plurality of semiconductor regions includes: forming a base region by ion implanting a dopant of a second conductivity type; implanting a dopant of a first conductivity type and a dopant of the second conductivity type at different ion implantation depths to form a junction structure of a first auxiliary region of the first conductivity type and a second auxiliary region of the second conductivity type; implanting a dopant of the first conductivity type into the base region to form a source region; and implanting a dopant of the first conductivity type to form a drain region.

In the disclosure, the source region and the drain region may be formed by one ion implantation process.

In the operation of forming a junction structure in the disclosure, ion implantation of the dopant of the first conductivity type and the dopant of the second conductivity type may be performed using one mask.

### Advantageous Effects of Invention

According to an aspect of the disclosure, the on-resistance characteristics of a SiC semiconductor device may be improved by doping a current path region at a high concentration. Further, the SiC device of the disclosure can significantly improve the breakdown voltage of the device by using a charge compensation effect.

In addition, according to another aspect of the disclosure, using an insulating or semi-insulating substrate makes it easy to design a charge balance for charge compensation, and thus a SiC semiconductor device capable of easily optimizing the device structure can be provided.

In addition, the disclosure does not have to grow an epi layer on a SiC substrate, and thus an on-axis SiC substrate can be used. Accordingly, there is no step-bunching, thus the surface is not rough, and there is no surface scattering problem which can occur on a rough surface, thereby making it possible to improve charge mobility.

A highly concentrated semiconductor region is formed on an insulating or semi-insulating SiC substrate, thereby making it possible to exhibit high withstand voltage characteristics. In addition, the withstand voltage characteristics of the SiC semiconductor device of the disclosure mainly depends on the length of the current path region, and thus the withstand voltage characteristics can be adjusted according to the length of the current path region.

In addition, according to still another aspect of the disclosure, ion implantation for forming a junction surface including a first auxiliary region and a second auxiliary region may be performed using one mask, and thus a junction surface forming process can be performed without an additional ion mask.

### BRIEF DESCRIPTION OF DRAWINGS

FIG. 1 is a diagram schematically illustrating a structure of a conventional SiC semiconductor device;

FIG. 2 is a diagram schematically illustrating a cross section of a lateral metal oxide semiconductor field effect transistor structure according to an embodiment of the disclosure;

FIGS. 3A and 3B are graphs showing results of computer simulation for an LMOSFET according to an embodiment of the disclosure;

FIGS. 4A to 4H are graphs showing results of computer simulation for an LMOSFET according to another embodiment of the disclosure;

FIGS. 5A to 5H are graphs showing results of computer simulation for an LMOSFET according to still another embodiment of the disclosure;

FIGS. 6A to 6F are procedural diagrams sequentially illustrating some of manufacturing processes of a lateral metal oxide semiconductor field effect transistor according to an embodiment of the disclosure; and

FIG. 7 is a diagram schematically illustrating a cross section of a lateral metal oxide semiconductor field effect transistor structure according to another embodiment of the disclosure.

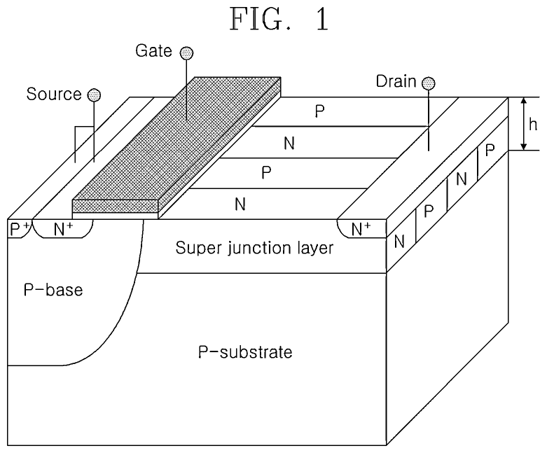

### BEST MODE FOR CARRYING OUT THE INVENTION

Hereinafter, embodiments of the disclosure will be described in detail with reference to the accompanying drawings.

The disclosure uses an insulating or semi-insulating substrate as a SiC substrate. In the description of the disclosure, an insulating substrate refers to one which has a resistance of 10⁷Ω-cm or more, and a semi-insulated substrate refers to one which has a resistance in the range of 10⁵ to 10⁷Ω-cm. Therefore, in the description of the disclosure, an insulating or semi-insulating substrate refers to a substrate having an electrical resistance of 10′Ω-cm or more. More specifically, in the disclosure, the resistance of the SiC substrate may be adjusted by controlling the content of impurities at the time of SiC single crystal growth. Typically, a pure SiC single crystal, which contains unintended impurities, may be used as a SiC substrate of the disclosure. Of course, in the disclosure, the insulating or semi-insulating substrate may satisfy the above-mentioned resistance conditions but may also contain intended impurities.

A SiC semiconductor device of the disclosure is configured to include a plurality of semiconductor regions formed by ion implantation inside the SiC substrate described above. In other words, the disclosure does not implement a semiconductor region using an epitaxial layer.

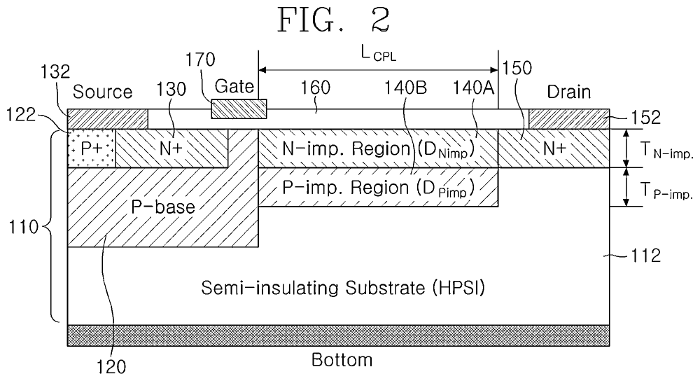

FIG. 2 exemplarily illustrates a SiC semiconductor device implemented according to an embodiment of the disclosure.

The device in FIG. 2 illustrates a metal oxide semiconductor field effect transistor (MOSFET) 100. However, a person skilled in the art could know that there is no difficulty in implementing other semiconductor devices, such as CMOS, according to the technical idea disclosed herein.

The device of FIG. 2 includes semiconductor regions 120, 122, 130, 140A, 140B, and 150 formed inside a substrate 110 and a resistance region 112.

In this embodiment, the SiC substrate may be a semi-insulated substrate having an electrical resistance of 10⁵ to 10⁷Ω-cm or an insulating substrate having an electrical resistance of 10⁷Ω-cm or more. Therefore, the electrical resistance of the resistance region 112 within the substrate is maintained at a resistance level inherent to the substrate.

In the disclosure, a plurality of semiconductor regions is formed inside a single crystal SiC substrate. That is, the SiC substrate may be configured of a single crystal body. Preferably, the SiC substrate may be implemented as a SiC single crystal wafer, and does not require a separate material layer, such as an epitaxial layer, to form a semiconductor region.

To implement a FET structure, the semiconductor regions include a source region 130, a drain region 150, and a base region 120, a first auxiliary region 140A, which functions as a current path and extends parallel to a substrate surface, is provided between the base region 120 and the drain region 150, and a second auxiliary region 140B is provided below the first auxiliary region 140A. In the disclosure, semiconductor regions such as the source region, the base region, and the drain region which constitute the field effect transistor are arranged in the transverse direction with respect to the surface of the SiC substrate.

As illustrated, the source region 130 is formed within a well of the base region 120 and forms a junction surface with the base region 120. Additionally, in the disclosure, a portion of the base region 120 may be implemented as a highly doped region 122 of a second conductivity type to maintain the source region 130 and the base region 120 at an equal potential.

A source electrode 132 and a drain electrode 152 are disposed on the source region 130 and the drain region 150, respectively.

In addition, a gate oxide film 160 is formed on the SiC substrate 110, and a gate electrode 170 is disposed between the source region and the current path region on the insulating film 160 while being surrounded by the insulating film 160.

In addition, a lower electrode 180 is provided at the lower end of the SiC substrate.

As illustrated, the base region 120 and the second auxiliary region 140B form a junction surface with the resistance region 112 of the SiC substrate. The drawing shows the drain region 150 forming a junction surface with the resistance region 112 as an embodiment of disclosure, but the disclosure is not limited thereto. For example, the second auxiliary region 140B may naturally extend toward a lower portion of the drain region 150, or another semiconductor region may be formed at a lower portion of the drain region 150.

In the disclosure, the source region 130, the drain region 150, and the first auxiliary region 140A are semiconductor regions of a first conductivity type, and the base region 120 and the second auxiliary region 140B is a semiconductor region of a second conductivity type different from the first conductivity type. Exemplarily, the source and drain regions may each be implemented as an n-type semiconductor region, the base region may be implemented as a p-type semiconductor region, and the current path region may be implemented as an n-type semiconductor region.

Typically, the amount of withstand voltage at which a FET device can withstand is determined by the doping concentration, length (LCPL), and thickness of the first auxiliary region 140A as a current path. In order to implement a high breakdown voltage, the impurity concentration in the first auxiliary region must be lowered. In addition, as the thickness of the first auxiliary region decreases, the breakdown voltage increases. However, there is a problem that if the concentration or thickness of the first auxiliary region is reduced to improve the breakdown voltage, the current movement path becomes narrow and the on-resistance of the device increases. Ultimately, in a conventional SiC device, when the doping concentration of the first auxiliary region is increased to secure on-resistance, a breakdown phenomenon occurs due to a high electric field at the gate or drain end in a reverse bias state, and thus it becomes impossible to achieve the high breakdown voltage of an insulating or semi-insulating SiC substrate.

To solve this problem, in the disclosure, the second auxiliary region 140B, which has a different conductivity type than the first auxiliary region, is disposed at a lower portion of the first auxiliary region 140A. The first auxiliary region 140A and the second auxiliary region 140B form a p/n junction surface parallel to the substrate surface, and a depletion region of the junction surface may extend to the entire first auxiliary region in a reverse bias state. Therefore, the lower portion of the second auxiliary region is an original resistance region of an insulating or semi-insulating SiC substrate having a very low concentration, and thus the maximum breakdown voltage of the device may not be affected by the concentration and thickness of the first auxiliary region and may have a value close to infinity.

In the disclosure, the concentration and thickness (or junction depth) of the first auxiliary region and the second auxiliary region may be appropriately designed according to the requirements for implementing the charge compensation effect.

According to an embodiment of the disclosure, the thickness of the first auxiliary region 140A may be designed to be equal to or greater than the thickness of the source region 130 and smaller than the thickness of the base region 120. Exemplarily, the thickness of the first auxiliary region 140A may be in the range of 0.1 to 0.5 m. In this way, the first auxiliary region 140A of the disclosure may be designed to have a low ion implantation depth, and high concentration doping may be facilitated by an ion implantation process.

In addition, in the disclosure, the doping concentration of the first auxiliary region 140A may be in the range of 1×10¹⁵/cm³ to 1×10¹⁷/cm³, or in the range of 1×10¹⁶/cm³ to 1×10¹⁷/cm³.

In the disclosure, the concentration of the second auxiliary region may be appropriately designed considering the charge compensation effect. For example, the second auxiliary region may be designed to have a doping concentration substantially the same as that of the first auxiliary region. Alternatively, the second auxiliary region may be designed to have a doping concentration different from that of the first auxiliary region.

For example, the ratio of the doping concentration of the second auxiliary region to the doping concentration of the first auxiliary region is preferably 0.7 to 1.3.

### MODE FOR CARRYING OUT THE INVENTION

The withstand voltage characteristics of the lateral metal oxide semiconductor field effect transistor implemented as shown in FIG. 2 were computer-simulated.

Silvaco's TCAD tool was used for computer simulation.

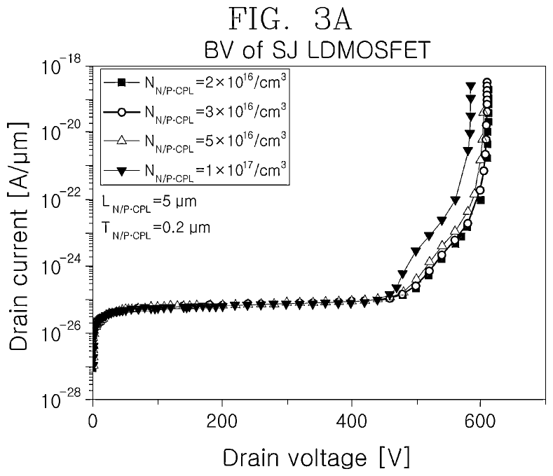

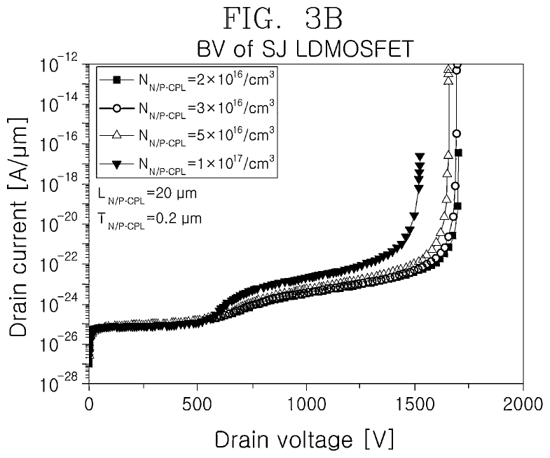

FIGS. 3A and 3B are graphs showing results of computer simulation in the case where the first auxiliary region and the second auxiliary region are designed to have the same concentration. The computer simulation conditions are as follows.
Substrate resistance: 10⁵Ω-cm
P-base concentration and junction depth: 3×10¹⁷/cm³, 0.6 um
N⁺ source/drain concentration and junction depth: 1×10²⁰/cm³, 0.2 um
Concentration of first auxiliary region/second auxiliary region (N_{N/P-CPL}): 2×10¹⁶/cm³˜1×10¹⁷/cm³
Thickness of first auxiliary region/second auxiliary region (T_{N/P-CPL}): 0.2 um
Length of first auxiliary region/second auxiliary region (L_{N/P-CPL}): Sum, 20 um

FIGS. 3A and 3B are graphs showing results of computer simulation in the case where the lengths of the first auxiliary region and the second auxiliary region are 5 μm and 20 um, respectively.

Referring to FIGS. 3A and 3B, it can be seen that a high breakdown voltage may be obtained even though the first auxiliary region has a high concentration of 2×10¹⁶/cm³ to 1×10¹⁷/cm³.

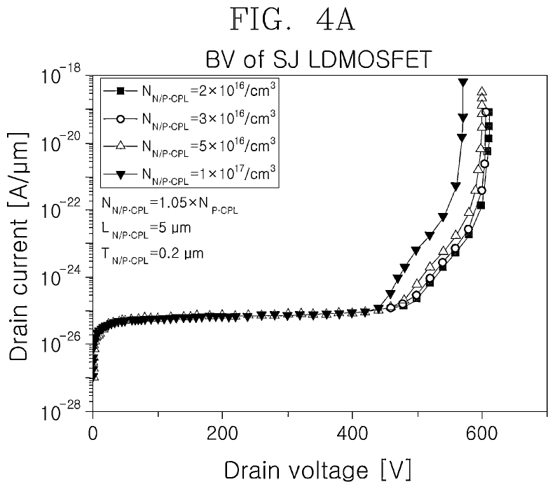

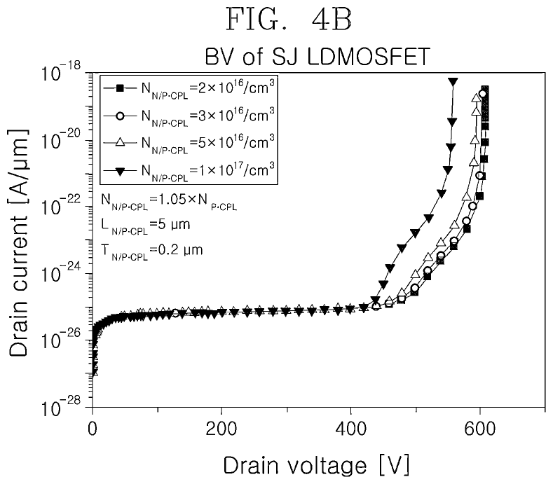

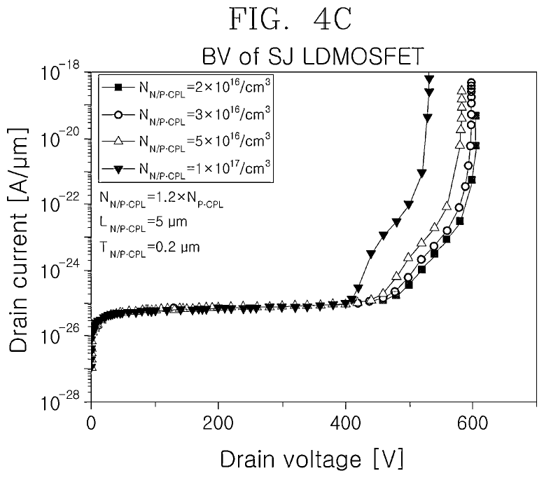

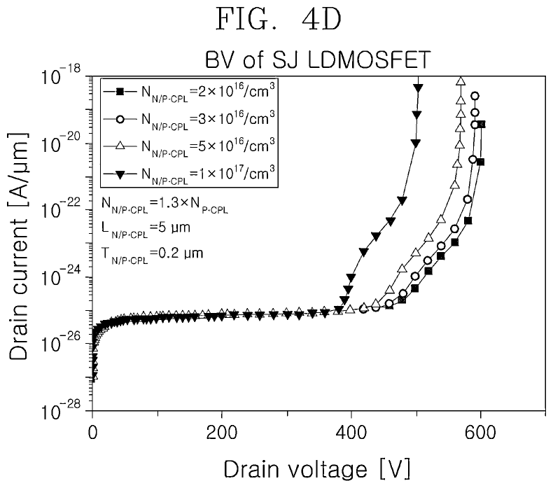

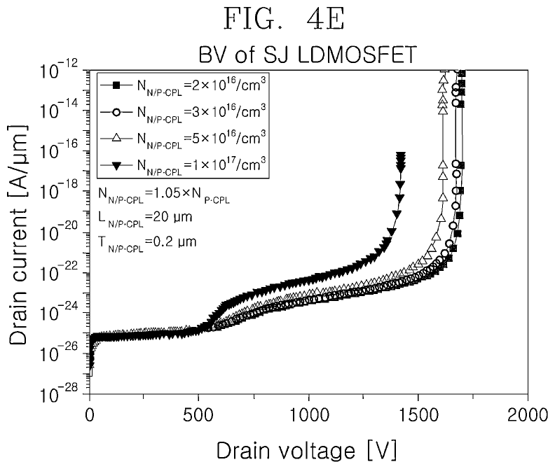

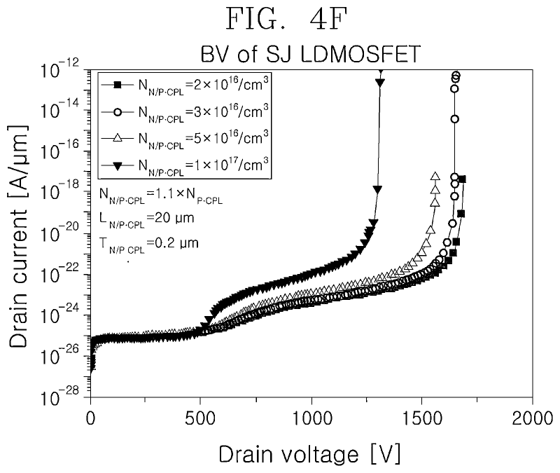

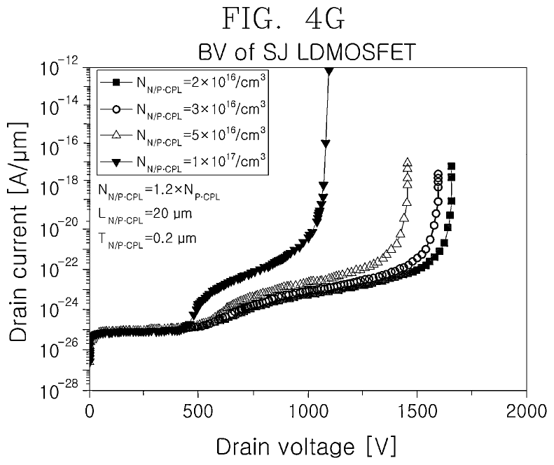

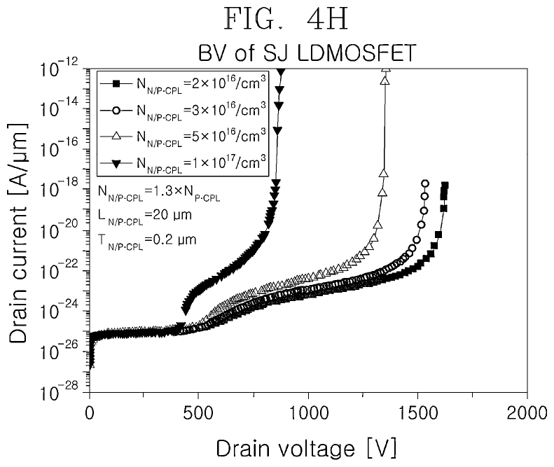

FIGS. 4A to 4H are graphs showing results of computer simulation in the case where the concentration of the second auxiliary region is designed to have a smaller value than the concentration of the first auxiliary region. The computer simulation conditions of FIGS. 4A to 4H were the same as those of FIGS. 3A and 3B except for the following conditions.
Concentration of second auxiliary region (N_{P-CPL}): 2×10¹⁶/cm³ to 1×10¹⁷/cm³
Concentration of first auxiliary region (N_{N-CPL}): 1.05 to 1.3 times that of N_{P-CPL} FIGS. 4A to 4D are computer simulation results in the case where L_{N/P-CPL}=5 μm, and FIGS. 4E to 4H are computer simulation results in the case where L_{N/P-CPL}=20 um.

Referring to FIGS. 4A to 4H, the breakdown voltage reduction amount was greater when the concentration of the first auxiliary region was 30% higher than that of the second auxiliary region, compared to the case where the concentration of the first auxiliary region was 5% higher than that of the second auxiliary region. This is believed to be because the charge compensation effect is reduced when the concentration of the first auxiliary region is higher than the concentration of the second auxiliary region. The second auxiliary region functions to deplete the first auxiliary region by combining the charges of the first auxiliary region in a reverse bias state. However, if the concentration of the first auxiliary region becomes higher than that of the second auxiliary region, the first auxiliary region cannot be completely depleted because the amount of charge required for depletion is insufficient, and thus the breakdown voltage decreases.

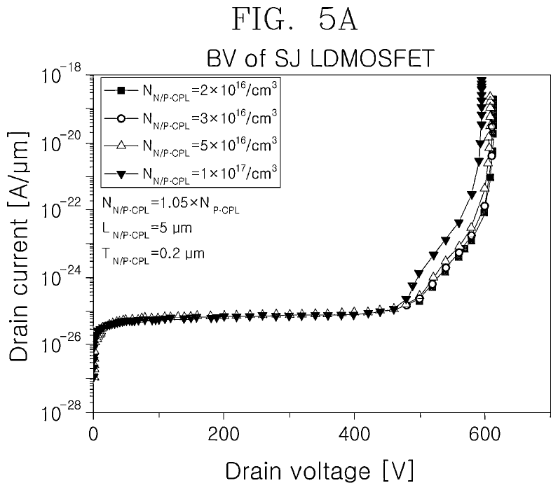

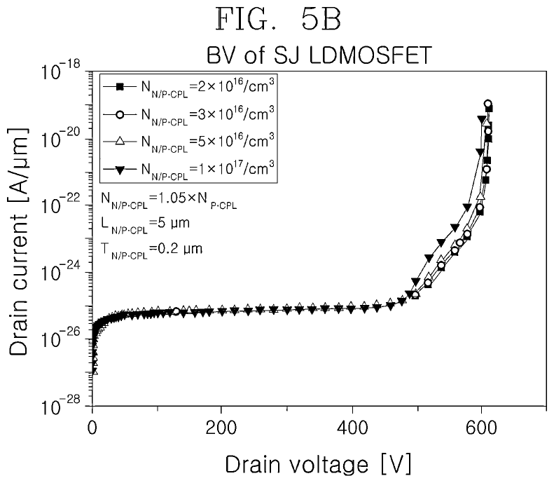

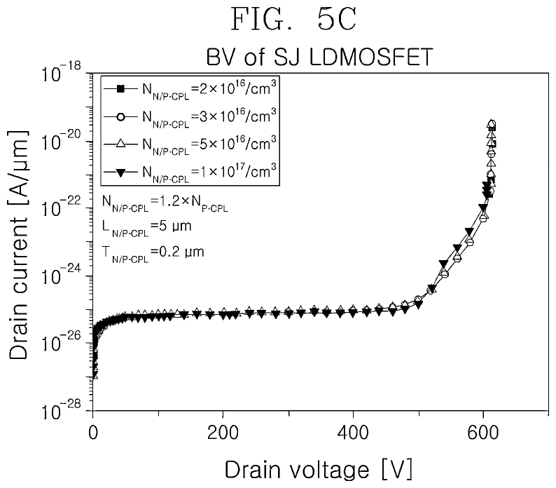

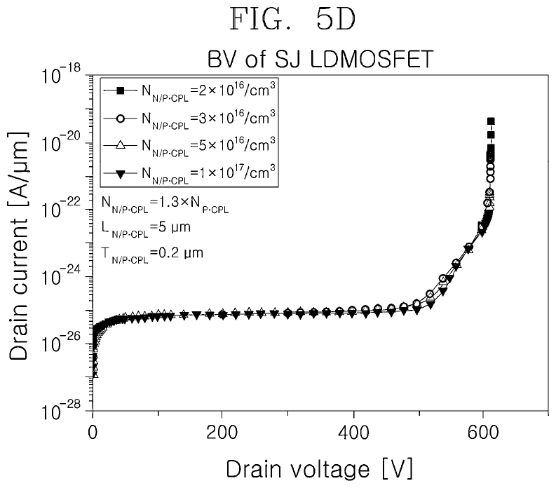

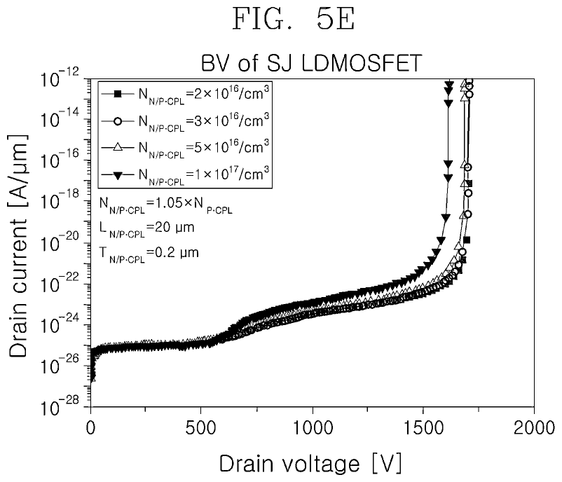

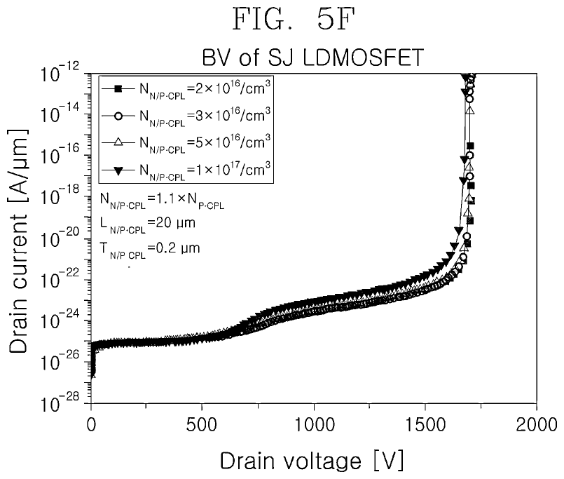

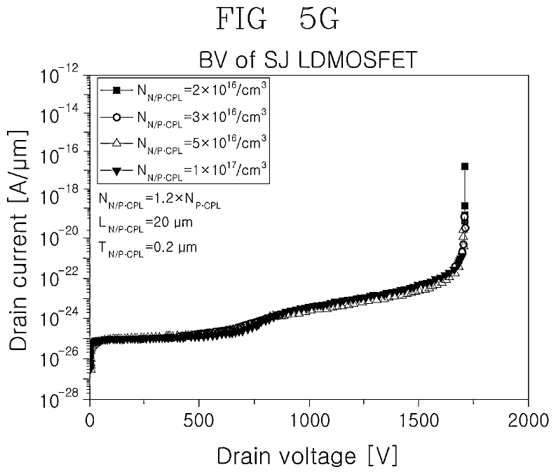

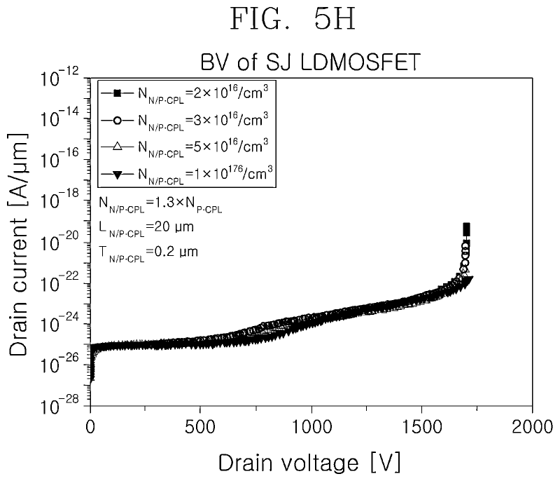

FIGS. 5A to 5H are graphs showing results of computer simulation in the case where the concentration of the second auxiliary region is designed to have a greater value than the concentration of the first auxiliary area. The computer simulation conditions of FIGS. 5A to 5H were the same as those of FIGS. 3A and 3B except for the following conditions.
Concentration of first auxiliary region (N_{N-CPL}): 2×10¹⁶/cm³ to 1×10¹⁷/cm³
Concentration of second auxiliary region (N_{P-CPL}): 1.05 to 1.3 times that of N_{N-CPL}

FIGS. 5A to 5D are graphs showing results of computer simulation in the case where L_{N/P-CPL}=5 μm, and FIGS. 5E to 5H are graphs showing results of computer simulation in the case where L_{N/P-CPL}=20 um.

Referring to FIGS. 5A to 5H, it can be seen that the breakdown voltage characteristics are more stable compared to the case where the concentration of the first auxiliary region is higher than that of the second auxiliary region. This is considered to be because the amount of charge required to completely deplete the first auxiliary region in a reverse bias state is sufficient.

Hereinafter, a method for manufacturing a SiC LMOSFET according to an embodiment of the disclosure will be described with reference to the drawings.

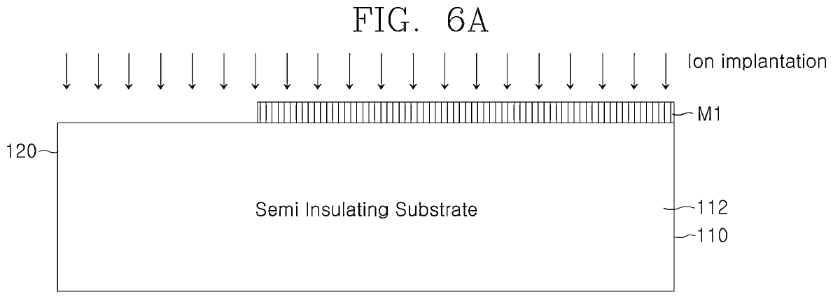

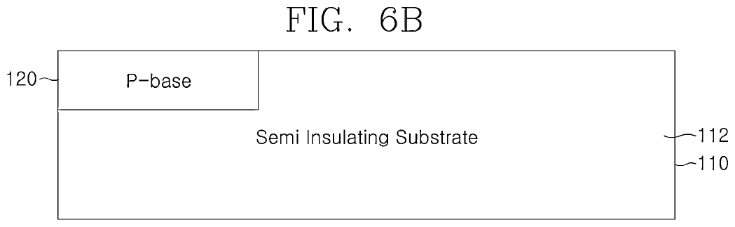

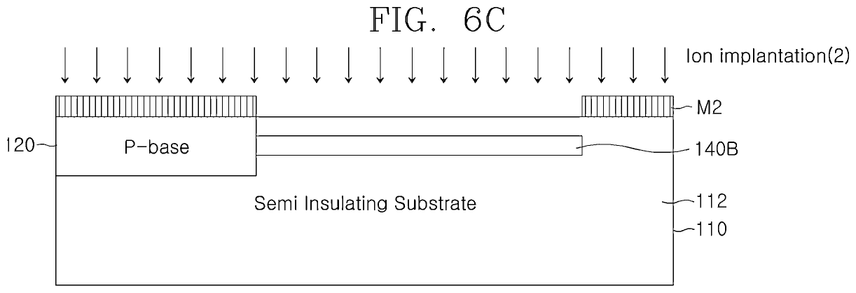

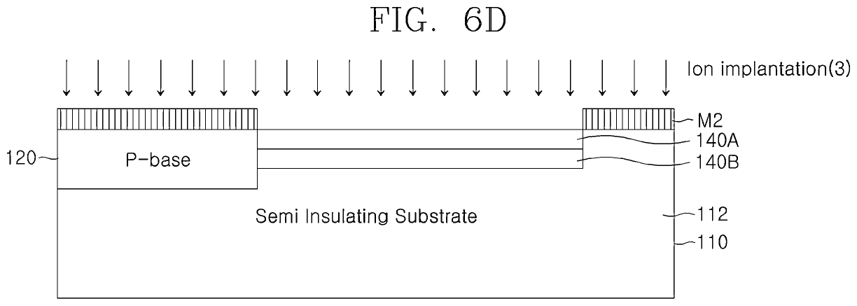

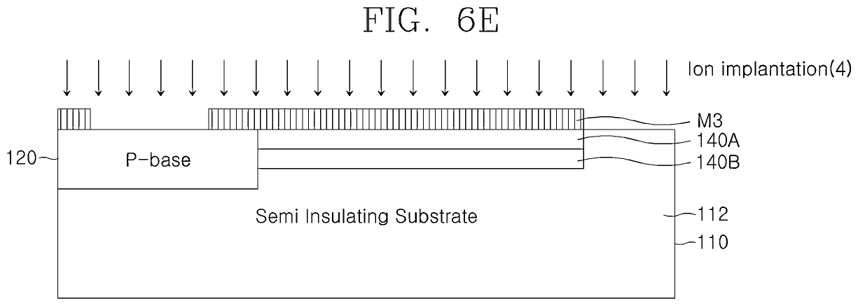

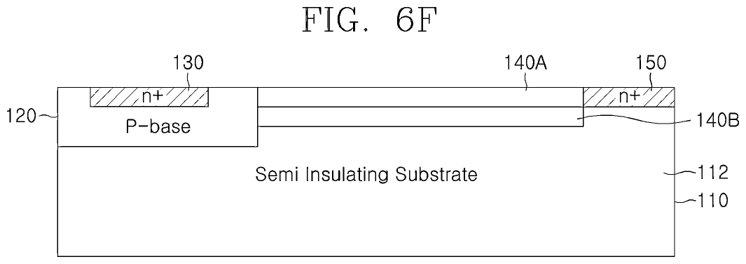

Referring to FIGS. 6A to 6F, a first ion implantation mask M1 configured to open a predetermined portion of the SiC substrate 110 is formed, and a dopant of a second conductivity type is ion implanted (a), thereby forming a base region (b). The implanted dopant may be B or A1, and the dopant concentration in the region formed by ion implantation is preferably within the range of 10¹⁶ to 10¹⁸/cm³. Exemplarily, in the disclosure, the ion implantation mask may be formed by a photoresist pattern, and for this purpose, a conventional photolithography technique may be used. In addition, in order to protect the crystal structure in the disclosure, ion implantation is preferably performed at a high temperature of 200° C. or higher. After ion implantation, the first ion implantation mask M1 is removed in a conventional manner such as ashing or lift-off.

Next, a second ion implantation mask M2 configured to open a predetermined portion of the SiC substrate 110 is formed, and a dopant of a second conductivity type is ion implanted, thereby forming a second auxiliary region (c). N or P may be used as the dopant to be implanted, the dopant concentration of the region formed by ion implantation may be in the range of 10¹⁵ to 10¹⁷/cm³, and the ion implantation depth is preferably in the range of 200 nm to 1000 nm. The ion implantation depth of the second auxiliary region may be determined to have the same thickness as the first auxiliary region below.

Next, the first auxiliary region is formed by ion implanting a dopant of the first conductivity type using the above-described second ion implantation mask M2 (d). N or P may be used as the dopant to be implanted, the dopant concentration of the region formed by ion implantation may be in the range of 10¹⁵ to 10¹⁷/cm³, and the ion implantation depth is preferably in the range of 100 nm to 500 nm.

Next, a source region and a drain region are formed by an ion implantation process (e, f). That is, a third ion implantation mask M3 is formed and N or P ions of the first conductivity type are implanted. The dopant concentration and ion implantation depth are preferably in the range of 10¹⁸ to 10²¹/cm³ and 100 nm to 300 nm, respectively.

Additionally, although not separately shown, a process of doping a portion of the base region at a high concentration may be added. This region maintains the source region and base region at equal potential. The dopant concentration is preferably 10¹⁸/cm³ or more.

As described above, in ion implantation processes, heat treatment is performed at high temperature to electrically activate implanted ions. The heat treatment temperature and time may be appropriately selected. Exemplarily, heat treatment may be performed at a temperature of 1600 to 1800° C. for a period of 10 minutes to 1 hour.

The ion implantation process described above exemplifies an embodiment of the disclosure. In contrast, a person skilled in the art could understand that the order of each ion implantation processes or the ion implantation conditions may be easily changed.

In addition, as a subsequent process to implement the structure illustrated in FIG. 2, the formation process of a gate oxide film, a gate electrode, a source electrode, and a drain electrode may be performed by a typical semiconductor process, and the description thereof will be omitted here.

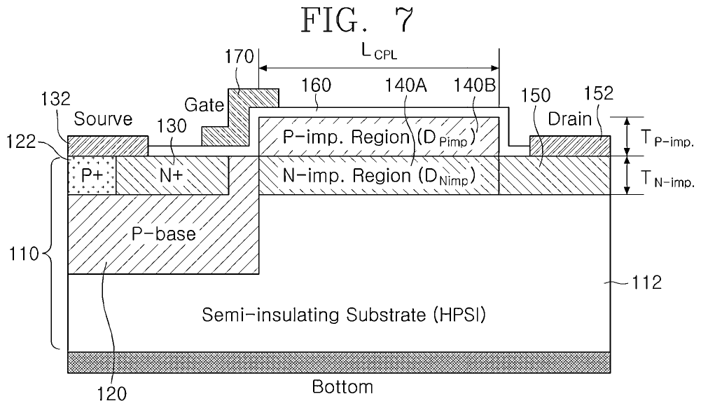

FIG. 7 is a diagram schematically illustrating a cross section of a lateral metal oxide semiconductor field effect transistor according to another embodiment of the disclosure.

In a device of FIG. 7, unlike the device described with reference to FIG. 2, a second auxiliary region 140B is disposed above a first auxiliary region 140A. For the operation of a FET, a gate and a drain have a recessed shape with respect to the second auxiliary region.

Although the embodiments of the disclosure have been described in detail above, it will be noted that the scope of the disclosure is not limited thereto, and various modifications and improvements which can be made by a person skilled in the art using the basic concept of the disclosure defined in the following claims also fall within the scope of rights of the disclosure.

### INDUSTRIAL APPLICABILITY

The disclosure is applicable to a silicon carbide (SiC) semiconductor device such as a MOSFET.

1. A SiC semiconductor device comprising a plurality of semiconductor regions comprising an insulation region formed at a second surface side in a SiC substrate having a first surface and a second surface, a source region formed on the insulation region along the first surface, a base region, and a drain region,
wherein the SiC semiconductor device comprises a P/N junction surface extending from the base region toward the drain region on the insulation region, formed by a first auxiliary region of a first conductivity type which is the same conductivity type as the source region and a second auxiliary region of a second conductivity type opposite to the first conductivity type, and parallel to the first surface.

2. The SiC semiconductor device of claim 1, wherein the first auxiliary region is disposed on the second auxiliary region.

3. The SiC semiconductor device of claim 1, wherein the first auxiliary region is disposed beneath the second auxiliary region.

4. The SiC semiconductor device of claim 1, wherein the doping concentration of the first auxiliary region is lower than the doping concentration of the source region.

5. The SiC semiconductor device of claim 1, wherein the doping concentration of the second auxiliary region is lower than the doping concentration of the base region.

6. The SiC semiconductor device of claim 1, wherein the ratio of the doping concentration of the second auxiliary region to the first auxiliary region is in the range of 0.7 to 1.3.

7. The SiC semiconductor device of claim 1, wherein the length of the second auxiliary region is substantially the same as the length of the first auxiliary region.

8. The SiC semiconductor device of claim 1, wherein the length of the second auxiliary region is greater than the length of the first auxiliary region.

9. The SiC semiconductor device of claim 1, wherein the insulation region has an electrical resistance of 10⁵Ω-cm or more.

10. The SiC semiconductor device of claim 1, wherein the base region extends between the source region and a current path region to a lower end of the source region to form a junction with the source region.

11. The SiC semiconductor device of claim 1, wherein the junction depth of the first auxiliary region is equal to or greater than the junction depth of the source region.

12. The SiC semiconductor device of claim 4, wherein the dopant concentration of the source and drain regions is 10¹⁸ to 10²¹/cm³.

13. The SiC semiconductor device of claim 4, wherein the dopant concentration of the base region is 1*10¹⁷ to 5*10¹⁷/cm³.

14. The SiC semiconductor device of claim 1, wherein the dopant concentration of the first auxiliary region is 10¹⁵/cm³ to 10¹⁷/cm³.

15. The SiC semiconductor device of claim 1, wherein the dopant concentration of the second auxiliary region is 10¹⁵/cm³ to 10¹⁷/cm³.

16. The SiC semiconductor device of claim 1, wherein the semiconductor device is a MOSFET or CMOS device.

17. A method for manufacturing a SiC semiconductor device, the method comprising:
providing an insulating or semi-insulating SiC substrate;
implanting a dopant into the SiC substrate to form a plurality of semiconductor regions; and
forming electrodes to electrically connect the plurality of doped regions on the SiC substrate,
wherein the operation of forming a plurality of semiconductor regions comprises:
forming a base region by ion implanting a dopant of a second conductivity type;
ion implanting a dopant of a first conductivity type and a dopant of the second conductivity type at different ion implantation depths to form a junction structure of a first auxiliary region of the first conductivity type and a second auxiliary region of the second conductivity type;
implanting a dopant of the first conductivity type into the base region to form a source region; and
implanting a dopant of the first conductivity type to form a drain region.

18. The method of claim 17, wherein the source region and the drain region are formed by one ion implantation process.

19. The method of claim 17, wherein in the forming of the junction structure, ion implantation of the dopant of the first conductivity type and the dopant of the second conductivity type is performed using one mask.
